(19) United States
(12) Patent Application Publication
(10) Pub. No.: US 2011/0175107 A1
(43) Pub. Date: Jul. 21, 2011

(54) SILICON CARBIDE SUBSTRATE

(75) Inventors: Taro NISHIGUCHI, Itami-shi (JP); Makoto Sasaki, Itami-shi (JP); Shin Harada, Osaka (JP); Kyoko Okita, Itami-shi (JP); Hiroki Inoue, Itami-shi (JP); Shinsuke Fujiwara, Itami-shi (JP); Yasuo Namikawa, Itami-shi (JP)

(73) Assignee: SUMITOMO ELECTRIC INDUSTRIES, LTD., Osaka-shi (JP)

(21) Appl. No.: 13/005,714

(22) Filed: Jan. 13, 2011

(30) Foreign Application Priority Data
Jan. 15, 2010 (JP) 2010-006827

(51) Int. Cl. H01L 29/16

(52) U.S. Cl. 257/77; 257/E29.084

(57) ABSTRACT

A base portion is made of silicon carbide and has a main surface. At least one silicon carbide layer is provided on the main surface of the base portion in a manner exposing a region of the main surface along an outer edge of the main surface. At least one protection layer is provided on this region of the main surface of the base portion along the outer edge of the main surface. Thus, a silicon carbide substrate can be polished with high in-plane uniformity.

### BACKGROUND OF THE INVENTION

1. Field of the Invention

The present invention relates to a silicon carbide substrate.

2. Description of the Background Art

An SiC (silicon carbide) substrate has recently increasingly been adopted as a semiconductor substrate used for manufacturing a semiconductor device. SiC has a bandgap wider than Si (silicon) that has more commonly been used. Therefore, a semiconductor device including an SiC substrate is advantageous in a high reverse breakdown voltage, a low ON resistance and less lowering in characteristics in an environment at a high temperature.

In order to efficiently manufacture a semiconductor device, a substrate is required to have a size not smaller than a certain size. According to U.S. Pat. No. 7,314,520, an SiC substrate not smaller than 76 mm (3 inches) can be manufactured.

A size of an SiC single-crystal substrate industrially remains as small as approximately 100 mm (4 inches) and hence it has not yet been able to efficiently manufacture a semiconductor device with the use of a large-sized single-crystal substrate. In making use of characteristics of a plane other than a (0001) plane in particular in hexagonal SiC, the problem above is particularly serious, which will be described below.

An SiC single-crystal substrate having fewer defects is normally manufactured by cutting an SiC ingot obtained by (0001) plane growth in which stacking faults are less likely. Therefore, a single-crystal substrate having a plane orientation other than the (0001) plane is cut in non-parallel to a growth surface. It is thus difficult to secure a sufficient size of a single-crystal substrate or a most part of an ingot cannot effectively be made use of. Thus, it is particularly difficult to efficiently manufacture a semiconductor device using a plane other than the (0001) plane of SiC.

Instead of increase in size of an SiC single-crystal substrate with such difficulties, use of a silicon carbide substrate including a base portion and a plurality of small single-crystal silicon carbide layers joined thereto is possible. This silicon carbide substrate can be increased in size as necessary, by increasing the number of single-crystal silicon carbide layers.

In an example where a silicon carbide layer is joined onto the base portion as described above, a portion not covered with a silicon carbide layer is formed in a region along an outer edge of the base portion, unless a shape of the silicon carbide layer accurately conforms to a shape of the base portion. Height difference is formed between this portion and a portion of the base portion where the silicon carbide layer has been joined. Presence of such height difference leads to excessive polishing of the silicon carbide layer at this portion of height difference during polishing such as chemical mechanical polishing (CMP). Consequently, in-plane uniformity in polishing becomes poor.

### SUMMARY OF THE INVENTION

The present invention was made in view of the above-described problems, and an object of the present invention is to provide a silicon carbide substrate that can be polished with high in-plane uniformity.

A silicon carbide substrate according to the present invention has a base portion, at least one silicon carbide layer and at least one protection layer. The base portion is made of silicon carbide and has a main surface. At least one silicon carbide layer is provided on the main surface of the base portion in a manner exposing a region of the main surface along an outer edge of the main surface. At least one protection layer is provided on this region of the main surface of the base portion, along the outer edge of the main surface.

According to the present invention, the protection layer provided on the region along the outer edge of the base portion lessens height difference between the region along the outer edge of the base portion and the silicon carbide layer. Thus, excessive polishing of a portion close to the outer edge of the base portion in the surface of the silicon carbide layer can be suppressed.

Preferably, at least one silicon carbide layer is a plurality of silicon carbide layers. Thus, as compared with a case where only a single silicon carbide layer is employed, an area of the silicon carbide substrate can be increased.

Preferably, the base portion is higher in dislocation density than at least one silicon carbide layer. Thus, the base portion can more readily be fabricated.

Preferably, the base portion is higher in impurity concentration than at least one silicon carbide layer. Thus, conductivity of the silicon carbide substrate can be enhanced.

Preferably, at least one protection layer has a thickness not exceeding a thickness of the silicon carbide layer. Thus, polishing of the silicon carbide layer is prevented from being interfered by the protection layer.

Preferably, at least one protection layer is made of silicon carbide. Thus, physical property of the protection layer can be close to physical property of the silicon carbide layer.

Preferably, at least one protection layer is higher in dislocation density than at least one silicon carbide layer. Thus, the protection layer can more readily be fabricated.

Preferably, at least one protection layer includes a portion having a thickness smaller than a thickness at a position facing the silicon carbide layer. Thus, since abrupt change in shape of a member for polishing the silicon carbide layer is prevented, in-plane uniformity in polishing can be enhanced.

Preferably, at least one protection layer surrounds the silicon carbide layer on the main surface. Thus, excessive polishing can be suppressed in the entire portion of the surface of the silicon carbide layer, that is close to the outer edge of the base portion.

Preferably, at least one protection layer includes a protection layer having a continuous loop shape. Thus, this single protection layer can suppress excessive polishing of the entire portion of the surface of the silicon carbide layer, that is close to the outer edge of the base portion.

Preferably, at least one protection layer is provided on the base portion such that a cavity is formed between each at least one protection layer and the base portion. This cavity mitigates stress in the silicon carbide substrate.

As can clearly be understood from the description above, according to the present invention, a silicon carbide substrate that can be polished with high in-plane uniformity can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view schematically showing a construction of a silicon carbide substrate in a first embodiment of the present invention.

FIG. 2 is a schematic cross-sectional view along the line II-II in FIG. 1.

FIG. 3 is a cross-sectional view schematically showing one step in a method of manufacturing a silicon carbide substrate in FIG. 1.

FIG. 4 is a plan view schematically showing a construction of a silicon carbide substrate in a second embodiment of the present invention.

FIG. 5 is a plan view schematically showing a construction of a silicon carbide substrate in a third embodiment of the present invention.

FIG. 6 is a plan view schematically showing a construction of a silicon carbide substrate in a fourth embodiment of the present invention.

FIG. 7 is a schematic cross-sectional view along the line VII-VII in FIG. 6.

FIGS. 8 to 11 are cross-sectional views schematically showing constructions of silicon carbide substrates in first to fourth variations of the fourth embodiment of the present invention, respectively.

FIG. 12 is a plan view schematically showing a construction of a silicon carbide substrate in a fifth embodiment of the present invention.

FIG. 13 is a schematic cross-sectional view along the line XIII-XIII in FIG. 12.

FIG. 14 is a cross-sectional view schematically showing one step in a method of manufacturing a silicon carbide substrate in FIG. 12.

### DESCRIPTION OF THE PREFERRED EMBODIMENTS

An embodiment of the present invention will be described hereinafter with reference to the drawings.

### First Embodiment

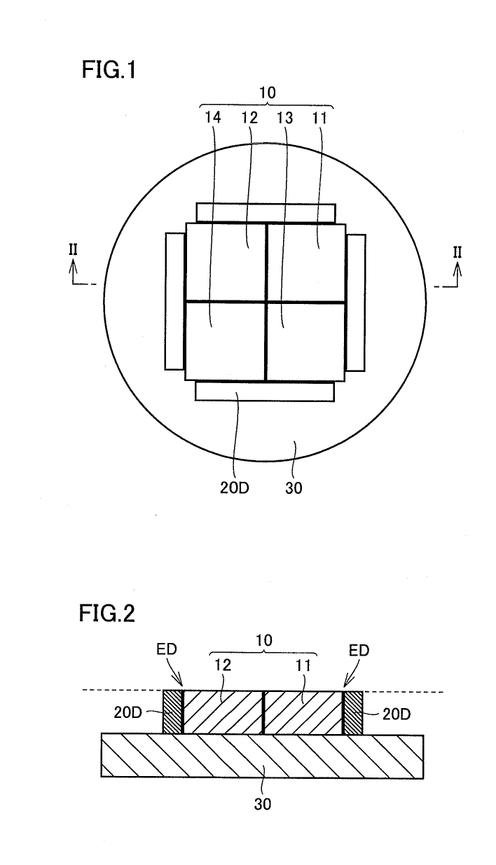

Referring to FIGS. 1 and 2, a silicon carbide substrate according to the present embodiment includes a base portion 30, silicon carbide layers 11 to 14 (collectively also referred to as group of layers 10), and a protection layer 20D.

Base portion 30 is made of silicon carbide and has a main surface (an upper surface in FIG. 2). Base portion 30 may be higher in dislocation density than each of silicon carbide layers 11 to 14, and thus base portion 30 having a large area can more readily be fabricated. In addition, under such a condition that dislocation density of base portion 30 may be high, base portion 30 can readily be higher in impurity concentration than each of silicon carbide layers 11 to 14, and thus conductivity of the silicon carbide substrate can be enhanced.

Each of silicon carbide layers 11 to 14 is provided on the main surface of base portion 30 in a manner exposing a region of the main surface of base portion 30, along an outer edge of the main surface. In addition, each of silicon carbide layers 11 to 14 has a single-crystal structure and hence satisfactory epitaxial growth can be achieved on silicon carbide layers 11 to 14.

Protection layer 20D is made of silicon carbide and provided on this region of the main surface of base portion 30 along the outer edge of the main surface. Protection layer 20D has a thickness not exceeding a thickness of each of silicon carbide layers 11 to 14 (a dashed line in FIG. 2), and thus polishing of silicon carbide layers 11 to 14 is prevented from being interfered by protection layer 20D. Protection layer 20D may be higher in dislocation density than each of silicon carbide layers 11 to 14 and thus protection layer 20D can more readily be fabricated.

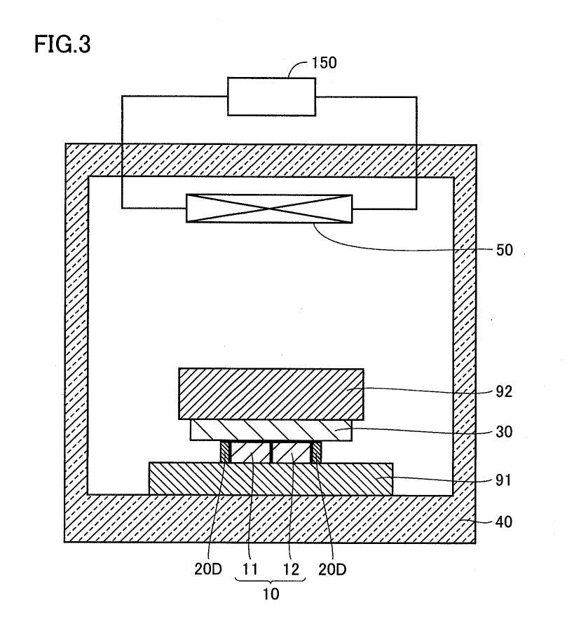

Referring to FIG. 3, a method of manufacturing a silicon carbide substrate according to the present embodiment will be described.

Initially, each of base portion 30, group of layers 10 constituted of silicon carbide layers 11 to 14 (FIG. 1), and protection layer 20D is prepared. Each layer in prepared group of layers 10 is a single-crystal silicon carbide substrate and a plane orientation thereof can be selected in accordance with an application of the silicon carbide substrate. For example, the plane orientation is a {0001} plane, a {03-38} plane, a {11-20} plane, or a plane inclined by a prescribed off angle from any of these planes. In addition, prepared base portion 30 is not limited to one made of single crystal and it may be polycrystalline. In the case of single crystal, base portion 30 may be higher in dislocation density than group of layers 10. Thus, it is not necessary to employ high-quality single crystal for base portion 30 as in the case of silicon carbide layers 11 to 14, and a sintered object may be employed. Therefore, a base portion larger than each of silicon carbide layers 11 to 14 can readily be prepared. For example, in an example where the base portion has a circular shape, it has a diameter preferably not smaller than 5 cm and further preferably not smaller than 15 cm.

Meanwhile, prepared protection layer 20D is composed of silicon carbide having a single-crystal structure. In this case, protection layer 20D may be higher in dislocation density than group of layers 10. Thus, it is not necessary to employ high-quality single crystal for protection layer 20D as in the case of silicon carbide layers 11 to 14, and a protection layer larger than each of silicon carbide layers 11 to 14 can readily be prepared.

A heating apparatus having first and second heating elements 91 and 92, a heat-insulating vessel 40, a heater 50, and a heater power supply 150 is prepared. Heat-insulating vessel 40 is formed of a highly heat-insulating material, and for example, it is formed of graphite. Heater 50 is, for example, an electric resistance heater. First and second heating elements 91 and 92 have a function to heat base portion 30 and group of layers 10 by radiating again heat obtained as a result of absorption of radiant heat from heater 50. First and second heating elements 91 and 92 are formed, for example, of graphite having low porosity.

Then, group of layers 10 and protection layer 20D are each arranged on first heating element 91, and base portion 30 and second heating element 92 are further arranged in a manner stacked thereon in this order. Specifically, initially on first heating element 91, group of layers 10 (FIG. 1: silicon carbide layers 11 to 14) is arranged in matrix and protection layer 20D is arranged at a position around the same. Then, base portion 30 is placed on a surface of group of layers 10 and protection layer 20D. Then, second heating element 92 is placed on base portion 30. Then, first heating element 91, group of layers 10, protection layer 20D, base portion 30, and second heating element 92 that are stacked are accommodated in heat-insulating vessel 40 in which heater 50 is provided.

Then, an atmosphere in heat-insulating vessel 40 is set to an inert gas atmosphere. For example, a noble gas such as He or Ar, a nitrogen gas, or a gas mixture of a noble gas and a nitrogen gas can be employed as the inert gas. In addition, a pressure in heat-insulating vessel 40 is set preferably to 50 kPa or lower and further preferably to 10 kPa or lower.

Then, heater 50 heats group of layers 10, protection layer 20D and base portion 30 to such a temperature as causing sublimation recrystallization reaction through each of first and second heating elements 91 and 92. Heating is carried out so as to produce such a temperature difference that a temperature of base portion 30 is higher than a temperature of group of layers 10. This temperature difference can be produced, for example, by arranging heater 50 nearer to second heating element 92 than to first heating element 91, as shown in FIG. 3.

When the temperature of base portion 30 is made higher than the temperature of each layer in group of layers 10 as described above, mass transfer due to sublimation recrystallization from base portion 30 toward group of layers 10 is caused in a small gap between each layer in group of layers 10 and base portion 30. Thus, each layer in group of layers 10 and base portion 30 are joined to each other. It is noted that a crystal structure of base portion 30 can change to a structure corresponding to a crystal structure of group of layers 10, as sublimation of base portion 30 and recrystallization thereof on group of layers 10 proceed.

Preferably, a gas containing nitrogen is employed as an inert gas to be introduced in heat-insulating vessel 40. Nitrogen atoms are taken into base portion 30 in a process of sublimation and recrystallization above. Consequently, concentration of an n-type impurity in base portion 30 of the silicon carbide substrate becomes higher.

According to the present embodiment, protection layer 20D provided on the region along the outer edge of base portion 30 lessens height difference between the region along the outer edge of base portion 30 and each of silicon carbide layers 11 to 14. Thus, excessive polishing of a portion close to the outer edge of base portion 30, in the surface of silicon carbide layers 11 to 14, can be suppressed during polishing of the silicon carbide substrate, and in particular, excessive polishing (chipping) of an edge portion ED (FIG. 2) of group of layers 10 can be prevented.

Though group of layers 10 and protection layer 20D are simultaneously joined to base portion 30 in the present embodiment, joint of group of layers 10 and joint of protection layer 20D may be performed in separate steps.

In addition, silicon carbide layers 11 to 14 are preferably lower in dislocation density than base portion 30 and protection layer 20D as described above. Regarding defects other than dislocation (such as a point defect or a plane defect) as well, silicon carbide layers 11 to 14 are preferably lower in defect density than base portion 30 and protection layer 20D.

Moreover, though silicon carbide which is a material for protection layer 20D has a single-crystal structure, silicon carbide serving as a material for protection layer 20D may have a polycrystalline structure. Since silicon carbide having a polycrystalline structure tends to be polished more readily than silicon carbide having a single-crystal structure, interference by protection layer 20D of polishing of the silicon carbide layer is prevented by employing silicon carbide having a polycrystalline structure as a material for protection layer 20D. Further, protection layer 20D composed of silicon carbide having a polycrystalline structure may be made of sintered silicon carbide, and in this case, protection layer 20D can readily be fabricated.

Furthermore, though protection layer 20D is made of silicon carbide in the present embodiment, a material for protection layer 20D is not limited thereto. In a case where protection layer 20D is joined to base portion 30 simultaneously with group of layers 10 through heating during manufacturing of a silicon carbide substrate, however, protection layer 20D should have high heat resistance, and in this case, a material for protection layer 20D preferably has a melting point not lower than 1000° C. Otherwise, a material having lower heat resistance can be employed, and for example, a resin material can be employed.

The main surface (the surface shown in FIG. 1) of protection layer 20D preferably has high evenness. In order to lessen influence on a process of manufacturing a semiconductor device including a silicon carbide substrate, a root mean square (RMS) is preferably less than 10 μm.

### Second Embodiment

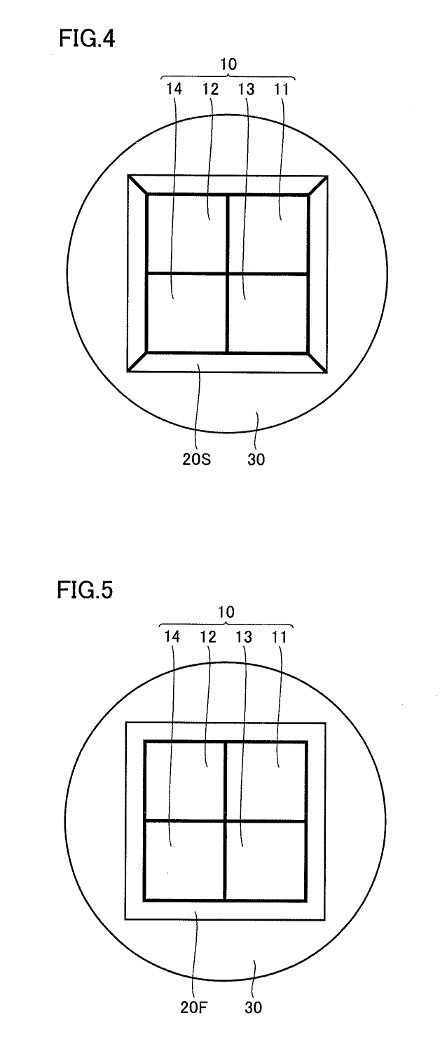

Referring mainly to FIG. 4, a silicon carbide substrate according to the present embodiment has a plurality of protection layers 20S instead of protection layer 20D (FIG. 1) in the first embodiment. Protection layers 20S surround group of layers 10 constituted of silicon carbide layers 11 to 14 on the main surface of base portion 30. Since the construction other than the above is substantially the same as in the first embodiment described above, the same or corresponding elements have the same reference characters allotted and description thereof will not be repeated. According to the present embodiment, during polishing of the surface of the silicon carbide substrate, excessive polishing can be suppressed in the entire portion of the surface of silicon carbide layers 11 to 14, that is close to the outer edge of base portion 30.

### Third Embodiment

Referring mainly to FIG. 5, a silicon carbide substrate according to the present embodiment has a protection layer 20F instead of the plurality of protection layers 20S (FIG. 4) in the second embodiment. Protection layer 20F has such a shape that the plurality of protection layers 20S are integrated. Therefore, protection layer 20F has a continuous loop shape. Since the construction other than the above is substantially the same as that in the second embodiment described above, the same or corresponding elements have the same reference characters allotted and description thereof will not be repeated. According to the present embodiment, excessive polishing can be suppressed by a single protection layer 20F in the entire portion of the respective surfaces of silicon carbide layers 11 to 14, that is close to the outer edge of base portion 30.

### Fourth Embodiment

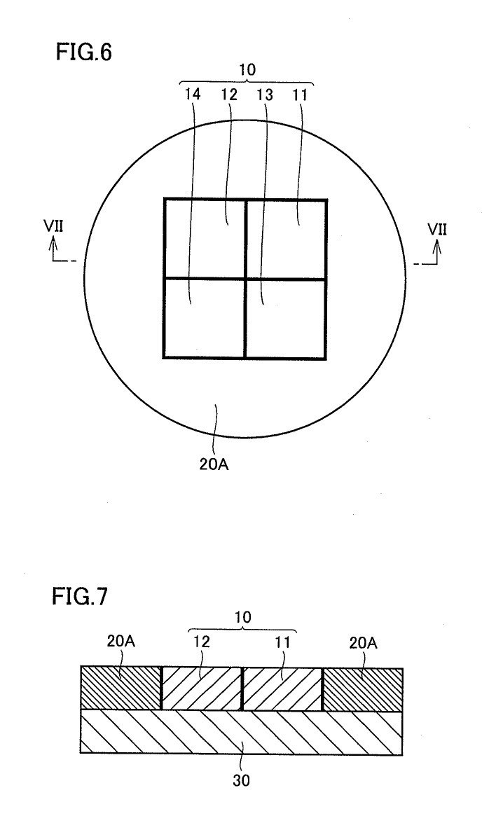

Referring mainly to FIGS. 6 and 7, a silicon carbide substrate according to the present embodiment has a protection layer 20A instead of protection layer 20F (FIG. 5) in the third embodiment. Protection layer 20A is provided on base portion 30 so as to cover the entire region of the main surface of base portion 30 that is not covered with group of layers 10 but is exposed along the outer edge of the main surface of base portion 30. In addition, protection layer 20A is equal in thickness to each layer in group of layers 10. Since the construction other than the above is substantially the same as in the third embodiment described above, the same or corresponding elements have the same reference characters allotted and description thereof will not be repeated. According to the present embodiment, height difference can be suppressed over the entire surface of the silicon carbide substrate.

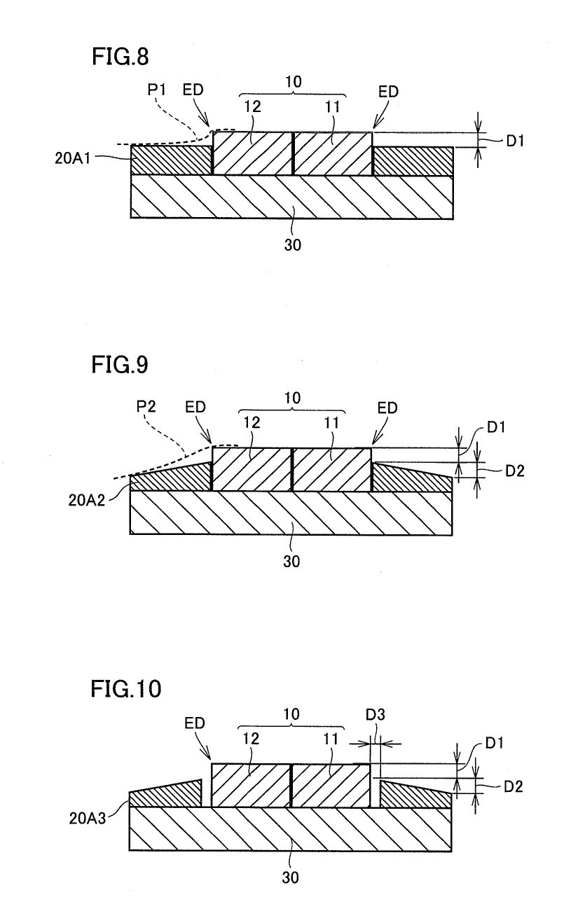

Referring to FIG. 8, a silicon carbide substrate according to a first variation of the present embodiment has a protection layer 20A1 instead of protection layer 20A (FIG. 7). Protection layer 20A1 is smaller in thickness than each layer in group of layers 10 by a dimension D1. Dimension D1 is less than 100 μm. In addition, dimension D1 is set such that protection layer 20A1 has a thickness not smaller than ⅔ and not larger than 1 of a thickness of each layer in group of layers 10. According to the present variation, interference by protection layer 20A1 of polishing of group of layers 10 is prevented.

In order to examine correlation between dimension D1 and occurrence of chipping, a thickness of the group of layers was fixed to 300 μm, a thickness of protection layer 20A1 was varied between 0 to 300 μm at a pitch of 50 μm, and 100 silicon carbide substrates were polished under each condition. After this polishing, whether chipping occurred or not at edge portion ED of each substrate was examined, to thereby find probability of occurrence of chipping. Table 1 below shows the results.

TABLE 1

| | | | | | | | |
|---|---|---|---|---|---|---|---|
| Outer | 0 | 50 | 100 | 150 | 200 | 250 | 300 |
| Peripheral | μm | μm | μm | μm | μm | μm | μm |
| Protection | | | | | | | |
| Layer | | | | | | | |
| Thickness | | | | | | | |
| Probability | 56/100 | 54/100 | 50/100 | 28/100 | 12/100 | 3/100 | 0/100 |
| of | | | | | | | |
| Chipping | | | | | | | |

Referring to FIG. 9, a silicon carbide substrate according to a second variation of the present embodiment has a protection layer 20A2 instead of protection layer 20A1 (FIG. 8). Protection layer 20A2 has a thickness smaller by a dimension D2 at a position facing an edge of base portion 30, with a thickness at a position facing group of layers 10 serving as a reference. According to the present variation, protection layer 20A2 includes a portion having a thickness smaller than a thickness at the position facing group of layers 10. Thus, since an abrasive cloth for polishing group of layers 10 gradually changes in shape as shown with a dashed line P2, this in-plane uniformity in polishing can be enhanced as compared with a case where this abrasive cloth abruptly changes in shape as shown with a dashed line P1 (FIG. 8). In particular, excessive polishing (chipping) of edge portion ED (FIG. 9) of group of layers 10 can further be prevented.

Referring to FIG. 10, a silicon carbide substrate according to a third variation of the present embodiment has a protection layer 20A3 instead of protection layer 20A2 (FIG. 9). Protection layer 20A3 is distant by a dimension D3 from edge portion ED of group of layers 10. Dimension D3 is less than 1 mm, and thus an effect of prevention by protection layer 20A3 of excessive polishing of edge portion ED is more reliably obtained.

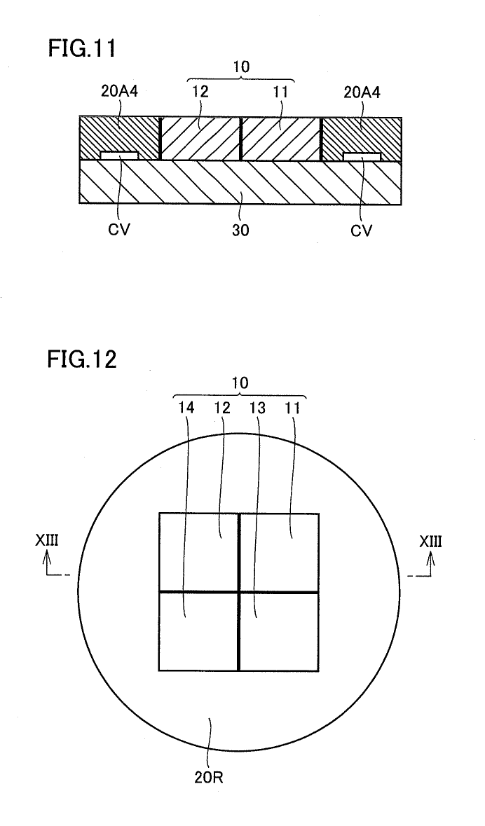

Referring to FIG. 11, a silicon carbide substrate according to a fourth variation of the present embodiment has a protection layer 20A4 instead of protection layer 20A (FIG. 7). Protection layer 20A4 is provided on base portion 30 so as to form a cavity CV between protection layer 20A4 and base portion 30. This cavity CV mitigates stress in the silicon carbide substrate.

It is noted that a variation similar to the first to fourth variations above is also applicable to the first to third embodiments.

### Fifth Embodiment

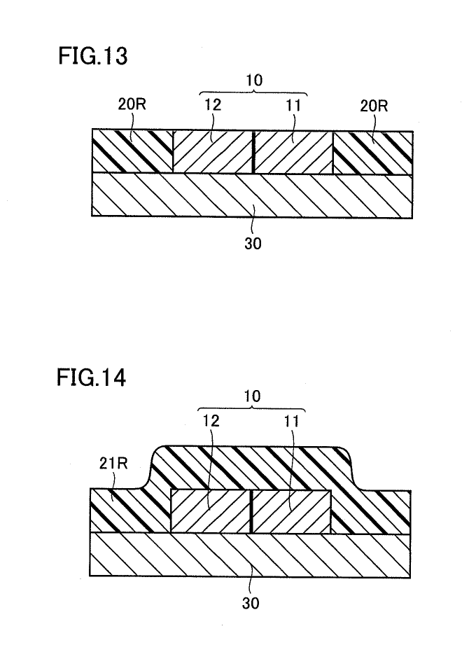

Referring to FIGS. 12 and 13, a silicon carbide substrate according to the present embodiment has a protection layer 20R instead of protection layer 20A (FIGS. 6 and 7) in the fourth embodiment. Protection layer 20R is made of a resin.

Referring to FIG. 14, a method of manufacturing a silicon carbide substrate according to the present embodiment will be described. Initially, base portion 30 to which group of layers 10 has been joined is prepared. This joint can be achieved with the method the same as in the first embodiment. Then, a liquid resin is applied onto the main surface of base portion 30, where group of layers 10 has been joined, and then this liquid resin is cured, so that a resin layer 21R is formed. Then, a portion of resin layer 21R on group of layers 10 is removed. In an example where a photoresist is adopted as the liquid resin, it can be removed by exposure and development. Alternatively, removal can also be achieved by polishing, and in this case, the liquid resin above is not limited to the photoresist. The silicon carbide substrate according to the present embodiment is obtained as above.

According to the present embodiment, the step of burying height difference in the silicon carbide substrate is performed by application of a liquid, and thus the height difference can more reliably be lessened.

It is noted that a joint surface between each layer in group of layers 10 and base portion 30 may be subjected to a planarization process in each embodiment above. If a silicon carbide substrate is employed for manufacturing a power semiconductor device, group of layers 10 preferably has a polytype of 4H. In addition, base portion 30 is preferably identical in crystal structure to group of layers 10. Difference in coefficient of thermal expansion between base portion 30 and group of layers 10 is preferably small to such an extent that a crack is not produced in a silicon carbide substrate during manufacturing of a semiconductor device including the silicon carbide substrate. Moreover, variation in in-plane thickness in the base portion and group of layers 10 is preferably small, and for example, it is preferably not greater than 10 μm. Further, base portion 30 preferably has low electrical resistivity, for example, lower than 50 mΩ•cm. Furthermore, the silicon carbide substrate preferably has a thickness not smaller than 300 μm. For example, a resistance heating method, an induction heating method or a lamp annealing method can be employed as a heating method for use in the heating apparatus (FIG. 3). The surface of group of layers 10 and the surface of the base portion opposed to each other are preferably identical in crystal orientation. As a method of attaching a protection layer to the base portion, an attachment method using an adhesive, a metal or an Si layer, or the like can also be employed other than the method using heat treatment. When a longest distance from the outer edge of base portion 30 to edge portion ED of group of layers 10 is not shorter than 1 mm and not longer than 20 mm, an effect of providing a protection layer is particularly high.

### EXAMPLE

A polycrystalline silicon carbide substrate having a circular shape was prepared as base portion 30 (FIG. 7). The substrate had a diameter of 10 cm, a thickness of 300 μm, an n conductive type, and impurity concentration of 1×10²⁰ cm⁻³. In addition, a plurality of square single-crystal silicon carbide substrates were prepared as group of layers 10 (FIG. 6). Each layer in group of layers 10 had a length of one side of 35 mm, a thickness of 300 μm, an n conductive type, impurity concentration of 1×10^{19 cm}⁻³, a polytype of 4H, a (0001) plane as a plane orientation, micropipe density lower than 1 cm⁻², and stacking fault density lower than 1 cm⁻¹. Moreover, a member having a thickness of 300 μm and composed of silicon carbide was prepared as protection layer 20A (FIG. 7). Then, the heating apparatus (FIG. 3) was used to join group of layers 10 and protection layer 20A to base portion 30. An operating condition of the heating apparatus was set such that a heating temperature was set to approximately 2000° C. as a temperature at which silicon carbide can sublimate, an atmosphere was formed by 100% nitrogen gas at a flow rate of 100 sccm, and a pressure was set to 133 Pa. The silicon carbide substrate (FIGS. 6 and 7) was obtained as above.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A silicon carbide substrate, comprising:
a base portion made of silicon carbide and having a main surface;
at least one silicon carbide layer provided on said main surface of said base portion in a manner exposing a region of said main surface along an outer edge of said main surface; and
at least one protection layer provided on said region of said main surface of said base portion.

2. The silicon carbide substrate according to claim 1, wherein
said at least one silicon carbide layer includes a plurality of silicon carbide layers.

3. The silicon carbide substrate according to claim 1, wherein
said base portion is higher in dislocation density than said at least one silicon carbide layer.

4. The silicon carbide substrate according to claim 1, wherein
said base portion is higher in impurity concentration than said at least one silicon carbide layer.

5. The silicon carbide substrate according to claim 1, wherein
said at least one protection layer has a thickness not exceeding a thickness of said silicon carbide layer.

6. The silicon carbide substrate according to claim 1, wherein
said at least one protection layer is made of silicon carbide.

7. The silicon carbide substrate according to claim 6, wherein
said at least one protection layer is higher in dislocation density than said at least one silicon carbide layer.

8. The silicon carbide substrate according to claim 1, wherein
said at least one protection layer includes a portion having a thickness smaller than a thickness at a position facing said silicon carbide layer.

9. The silicon carbide substrate according to claim 1, wherein
said at least one protection layer surrounds said silicon carbide layer on said main surface.

10. The silicon carbide substrate according to claim 1, wherein
said at least one protection layer includes a protection layer having a continuous loop shape.

11. The silicon carbide substrate according to claim 1, wherein
said at least one protection layer is provided on said base portion such that a cavity is formed between each said at least one protection layer and said base portion.
